(19) United States
(12) Patent Application Publication
(10) Pub. No.: US 2015/0034246 A1
(43) Pub. Date: Feb. 5, 2015

(54) CHEMICAL MECHANICAL POLISHING FASTENING FIXTURE AND FASTENING BASE

(71) Applicant: K-Chwen Technology Corporation, Ltd., Hsinchu City (TW)

(72) Inventor: Hui-Chen Yen, Hsinchu City (TW)

(73) Assignee: K-Chwen Technology Corporation, Ltd., Hsinchu City (TW)

(21) Appl. No.: 13/956,664

(22) Filed: Aug. 1, 2013

(51) Int. Cl. H01L 21/687

(52) U.S. Cl. CPC H01L 21/68721
USPC 156/345.14

(57) ABSTRACT

A chemical mechanical polishing fastening fixture includes a fastening base and a fastening ring. The fastening base includes an annular substrate having a first combining face and a plurality of protruded blocks annularly aligned on the first combining face. Each protruded block is made of polyphenylene sulfide and includes a first buckling face. The first buckling face is tilted from a root portion thereof toward an outer side of the protruded block along a plane radially extending from the annular substrate. The fastening ring has a second combing face and a plurality of first grooves. The first grooves are annularly aligned on the second combining face. Parts of a flange of each first groove are constituted of a second buckling face, and the second buckling face is tilted from a root portion thereof toward the second combining face.

### BACKGROUND

1. Technical Field

The disclosure relates to a wafer fastening fixture, and particularly to a chemical mechanical polishing fastening fixture and fastening base.

2. Related Art

Wafer fastening fixtures are essentially basic tools during manufacturing the semiconductor and are applied for loading the wafers, so that the wafers are moved, processing chemical procedures and so forth conveniently during semiconductor manufacturing process.

Please refer to FIG. 1, which is a conventional wafer fastening fixture provided by the semiconductor apparatus manufacturers. The conventional wafer fastening fixture includes a fastening base 10 and a fastening ring 20. The fastening base 10 is made of stainless steel and is disposed on a semiconductor processing equipments. The fastening ring 20 is made of high level plastics and provided for loading the wafer. The fastening ring 20 is attached onto the fastening base 10 via adhesives; however, since the attaching face 11 of the fastening base 10 is flat, once the adhesives fails to attach the fastening ring 20 with the fastening base 10, the fastening ring 20 and the fastening base 10 are separated.

Therefore, the conventional wafer fastening fixture has to be renewed frequently due to the issue mentioned above so that the manufacturing cost of the wafer is increased. Besides, the wafer fastening fixtures with low quality will damage the wafer. Hence, the structure of the wafer fastening fixture has to be improved so as to possess high stability and sustainability for significantly reducing the manufacturing cost of the wafer.

### SUMMARY

In view of this, the disclosure proposes a chemical mechanical polishing fastening fixture which is easy to be assembled, easy to be manufactured, as well as possess high stability and sustainability, so that the manufacturing cost of wafer can be reduced.

One concept of the disclosure provides a chemical mechanical polishing fastening fixture. The chemical mechanical polishing fastening fixture includes a fastening base and a fastening ring. The fastening base includes an annular substrate having a first combining face and a plurality of protruded blocks annularly aligned on the first combining face. Each protruded block is made of polyphenylene sulfide and includes a first buckling face. The first buckling face is tilted from a root portion thereof toward an outer side of the protruded block along a plane radially extending from the annular substrate. The fastening ring has a second combing face and a plurality of first grooves. The first grooves are annularly aligned on the second combining face. Parts of a flange of each first groove are constituted of a second buckling face, and the second buckling face is tilted from a root portion thereof toward the second combining face. When the protruded blocks are disposed in the first grooves, the fastening base and the fastening ring are rotated counterclockwise respectively along the circumference thereof, so that the first buckling face of the protruded block is buckled with the second buckling face of the first groove.

Another concept of the disclosure provides a fastening base of a chemical mechanical polishing fastening fixture. The fastening base is provided to combine with a fastening ring so as to form the chemical mechanical polishing fastening fixture. The fastening ring has a second combining face and a plurality of first grooves. The first grooves are annularly aligned on the second combining face. Parts of a flange of each first groove are constituted of a second buckling face. The second buckling face is tilted from a root portion thereof toward the second combining face. The fastening base includes an annular substrate having a first combining face and a plurality of protruded blocks annularly aligned on the first combining face. Each protruded block is made of polyphenylene sulfide and includes a first buckling face. The first buckling face is tilted from a root portion thereof toward an outer side of the protruded block along a plane radially extending from the annular substrate. When the protruded blocks are disposed in the first grooves, the fastening base and the fastening ring are rotated counterclockwise respectively along the circumference thereof, so that the first buckling face of the protruded block is buckled with the second buckling face of the first groove.

A further concept of the disclosure provides a chemical mechanical polishing fastening fixture.

The chemical mechanical polishing fastening fixture includes a fastening base and a fastening ring. The fastening ring includes an annular substrate having a first combining face and a plurality of protruded blocks annularly aligned on the first combining face. Each protruded block is made of polyphenylene sulfide and includes a first buckling face. The first buckling face is tilted from a root portion thereof toward an outer side of the protruded block along a plane radially extending from the annular substrate. The fastening base has a second combing face and a plurality of first grooves. The first grooves are annularly aligned on the second combining face. Parts of a flange of each first groove are constituted of a second buckling face, and the second buckling face is tilted from a root portion thereof toward the second combining face. When the protruded blocks are disposed in the first grooves, the fastening base and the fastening ring are rotated counterclockwise respectively along the circumference thereof, so that the first buckling face of the protruded block is buckled with the second buckling face of the first groove.

The detailed features and advantages of the disclosure are described below in great detail through the following embodiments, the content of the detailed description is sufficient for those skilled in the art to understand the technical content of the disclosure and to implement the disclosure there accordingly. Based upon the content of the specification, the claims, and the drawings, those skilled in the art can easily understand the relevant objectives and advantages of the disclosure.

### BRIEF DESCRIPTION OF THE DRAWINGS

The disclosure will become more fully understood from the detailed description given herein below for illustration only and thus not limitative of the disclosure, wherein:

FIG. 1 is a perspective view of a conventional wafer fastening fixture;

FIGS. 2A and 2B are schematic views of a chemical mechanical polishing fastening fixture of the disclosure;

FIGS. 3A to 3G are partial enlarged views of the circle 6 shown in FIG. 2B for showing embodiments of the fastening base of the disclosure;

FIGS. 4A to 4G are cross-sectional views of FIGS. 3A to 3G respectively,

FIG. 4H is a cross-sectional view of the fastening base according to one embodiment of the disclosure, showing protruded blocks and annular substrate of the fastening base are formed integrally as a whole;

FIG. 5A is a partial enlarged view of a fastening ring of the disclosure;

FIG. 5B is a cross-sectional view of a fastening ring of the disclosure;

FIG. 6A is an exploded schematic view of the fastening base shown in FIG. 4A and the fastening ring shown in FIG. 5B;

FIG. 6B is an assembled schematic view of the fastening base shown in FIG. 4A and the fastening ring shown in FIG. 5B.

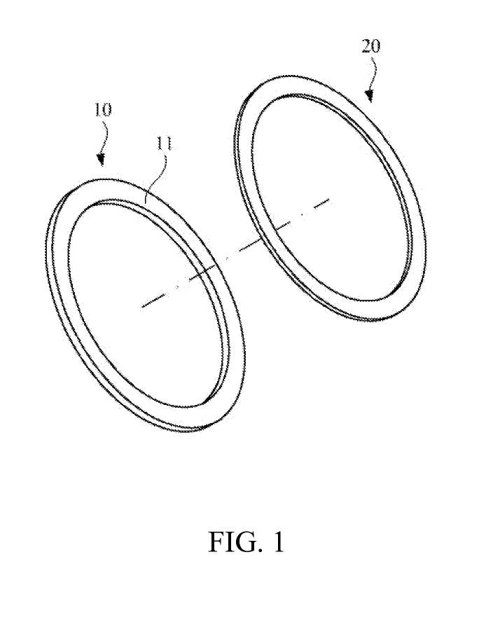

### DETAILED DESCRIPTION

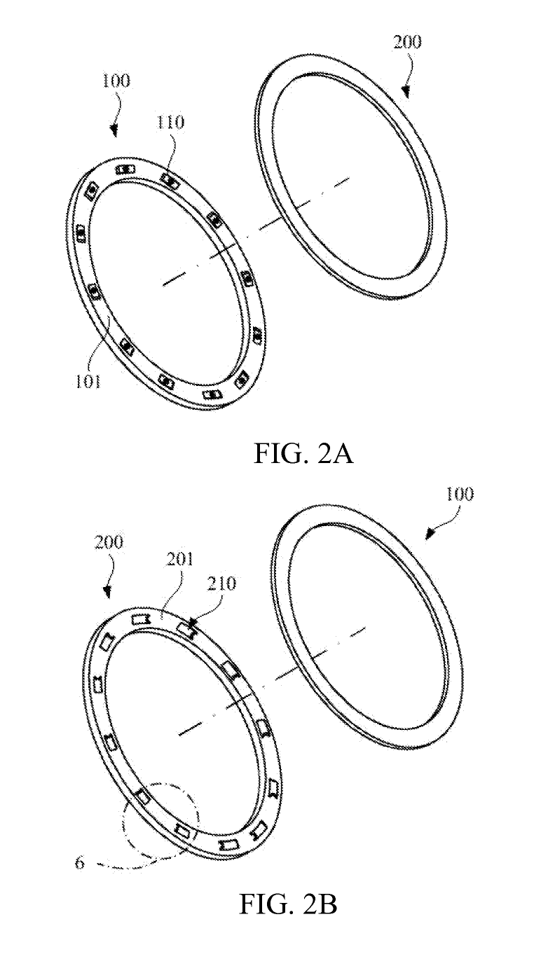

Please refer to FIGS. 2A to 2B, a chemical mechanical polishing fastening fixture of the disclosure includes a fastening base 100, a fastening ring 200, at least one protruded block 110 and at least one first groove 210.

The fastening base 100 includes an annular substrate which has a first combining face 101; that is to say, the fastening base has the first combining face 101, and the first combining face 101 is an annular face. The fastening base 100 can be made of stainless steel. The first combining face 101 has a plurality of protruded blocks 110 disposed thereon, and the protruded blocks 110 are annularly aligned and can also be made of stainless steel; but embodiments of the disclosure are not limited thereto, in some embodiments, the protruded blocks 110 are made of polyphenylene sulfide (PPS). The fastening ring 200 has a second combining face 201 and a plurality of first grooves 210 corresponding to the protruded blocks 110. The fastening ring 200 can be made of high level plastics. The fastening base 100 and the fastening ring 200 can be rotated counterclockwise respectively along the circumference thereof, so that the protruded blocks 110 are buckled with the first grooves 210, and the first combining face 101 is closely contacted with the second combining face 201. Then, adhesives are applied to fasten the fastening base 100 and the fastening ring 200 securely so as to form a structure with high stability and sustainability. The options of the adhesive are known by skilled in the arts so as to be omitted.

Practically, the protruded blocks 110 and the fastening base 100 can be formed integrally as a whole, or can be made separately. Several embodiments are described below.

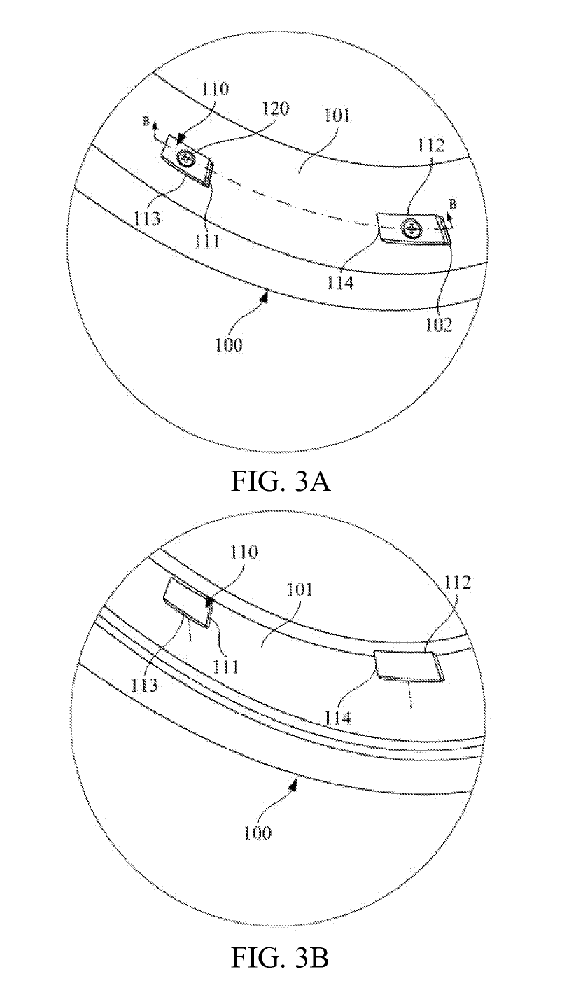

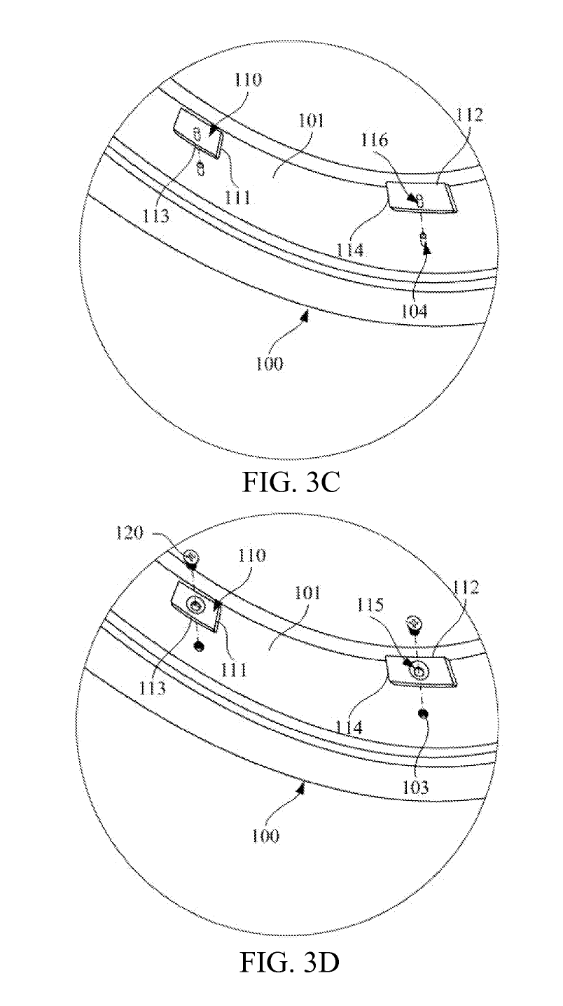

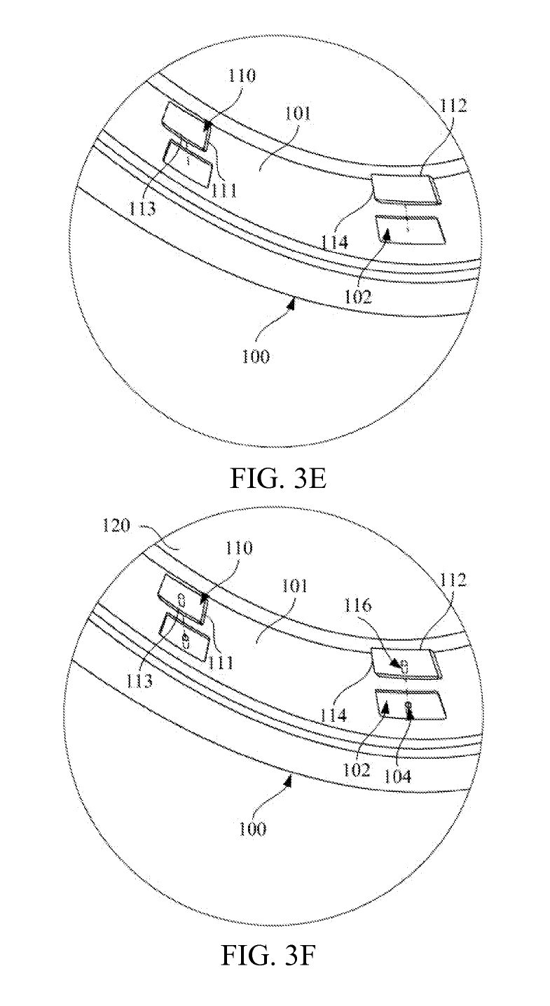

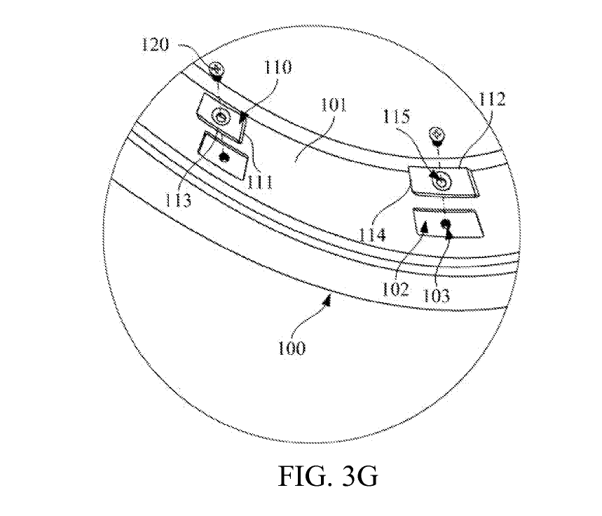

Please refer to FIGS. 3A to 3G, which are partial enlarged views of the circle 6 shown in FIG. 2B for showing several embodiments of the fastening base 100 of the disclosure respectively.

Firstly, please refer to FIG. 3A, which is an assembled view of the fastening base 100 of the embodiment shown in FIG. 3G and presents one embodiment showing the annular substrate of the fastening base 100 and the protruded blocks 110 are manufactured separately. As shown in FIG. 3A and FIG. 3G, the protruded blocks 110 are secured on the annular substrate of the fastening base 100 via a plurality of screw bolts 120, and the annular substrate has a plurality of second grooves 102 to receive the protruded blocks 110 and prevent the protruded blocks 110 from shifting.

Each protruded block 110 includes a first top face (namely, the top face of the protruded block 110), a first guiding face 111, a first inner lateral face 112, a first outer lateral face 113, a first buckling face 114 and a first through hole 115 (as shown in FIG. 3G). The first buckling face 114 is tilted from the root portion (namely, the intersection portion of the first buckling face 114 and the first combining face 101) thereof toward the outer side of the protruded block 110 along a plane radially extending from the annular substrate of the fastening base 100 (but embodiments of the disclosure are not limited thereto) and formed as one reversed clamp structure. The first inner lateral face 112 and the first outer lateral face 113 are arc faces extending from the circumference of the fastening base 100, and the curvature radii of the first inner lateral face 112 is smaller than the curvature radii of the first outer lateral face 113. The first top face is the top portion of a plane constituted of the protruded block 110. In this embodiment, preferably, a tilt angle of the first buckling face 114 is 30 degrees. Preferably, the first guiding face 111 is the plane radially extending along the fastening base 100 (but embodiments of the disclosure are not limited thereto) and cooperates with the first buckling face 114 to guide the first grooves 210 to securely buckled with the protruded blocks 110. In this embodiment, preferably the first guiding face 111 is vertically disposed on the first combining face 101, but embodiments of the disclosure are not limited thereto; the first guiding face 111 can tilt from the root portion (namely, the intersection portion of the first guiding face 111 and the first combining face 101) of the first guiding face 111 toward the inner side of the protruded block 110. In one embodiment, the first guiding face 111 is disposed opposite to the first buckling face 114 and is parallel to the first buckling face 114.

And then, please refer to FIGS. 3B to 3G, which shows several embodiments of the disclosure.

FIG. 3B is a schematic view of one embodiment of the fastening base 100. In this embodiment, the protruded blocks 110 are manufactured separately and are fastened on the annular substrate of the fastening base 100 via adhesives. In this embodiment, the positions of the protruded blocks 110 are pre-determined on the fastening base 100, and then the adhesives are applied to fasten the protruded blocks 110 with the fastening base 100. Here, the structure of the protruded blocks 110 is the same as mentioned above so as to be omitted.

FIG. 3C is a schematic view of another embodiment of the fastening base 100. In this embodiment, the protruded blocks 110 are manufactured separately, and each protruded block 110 has a protruded rod 116. A plurality of recessed holes 104 is disposed on the annular substrate of the fastening base 100 in advance for corresponding to the protruded rods 116. Therefore, the protruded rods 116 can be inserted into the recessed holes 104 and fastened on the annular substrate of the fastening base 100 via the adhesives. In this embodiment, because of the protruded rod 116 and the recessed hole 104, each protruded block 110 can be positioned precisely, and can be fastened on the fastening base 100 via the adhesives. Here, the structure of the protruded blocks 110 is the same as mentioned above so as to be omitted.

FIG. 3D is a schematic view of a further embodiment of the fastening base 100. In this embodiment, the protruded blocks 110 are manufactured separately, and are threaded with the annular substrate of the fastening base 100 via the screw bolts 120. In this embodiment, the first through holes 115 are opened on the protruded blocks 110 in advance, and a plurality second through holes 103 is opened on the annular substrate of the fastening base 100 in advance. Each second through hole 103 is corresponding to and is opposite to each corresponding first through hole 115. Before the screw bolts 120 pass through the first through holes 115 and the second through holes 103 to thread with the annular substrate, the adhesives can be applied to enhance the structural strength between the protruded blocks 110 and the annular substrate of the fastening base 100. Here, the structure of the protruded blocks 110 is the same as mentioned above so as to be omitted.

FIG. 3E is a schematic view of a yet another embodiment of the fastening base 100. In this embodiment, the protruded blocks 110 are manufactured separately, and are attached on the annular substrate of the fastening base 100 via the adhesives. In this embodiment, the second grooves 102 are formed on the annular substrate of the fastening base 100 in advance so as to receive the protruded blocks 110 therein. The second grooves 102 are provided to secure and position the protruded blocks 110 transversely, and the adhesives are provided to fasten the protruded blocks 110 with the annular substrate of the fastening base 100 longitudinally. That is to say, each second groove 102 receives each corresponding protruded block 110 so as to prevent each corresponding protruded block 110 from sliding. Here, the structure of the protruded blocks 110 is the same as mentioned above so as to be omitted.

FIG. 3F is a schematic view of a still another embodiment of the fastening base 100. In this embodiment, the protruded blocks 110 are manufactured separately, and each protruded block 110 has the protruded rod 116. The recessed holes 104 are disposed on the annular substrate of the fastening base 100 in advance for corresponding to the protruded rods 116. Therefore, the protruded rods 116 can be inserted into the recessed holes 104 and fastened on the annular substrate of the fastening base 100 via the adhesives. In this embodiment, because of the protruded rod 116 and the recessed hole 104, each protruded block 110 can be positioned precisely, and can be fastened on the fastening base 100 via the adhesives. Besides, in this embodiment, the second grooves 102 are also formed on the annular substrate of the fastening base 100 in advance so as to receive the protruded blocks 110 therein. The second grooves 102 are provided to secure and position the protruded blocks 110 transversely, and the adhesives are provided to fasten the protruded blocks 110 with the annular substrate of the fastening base 100 longitudinally. Here, the structure of the protruded blocks 110 is the same as mentioned above so as to be omitted.

FIG. 3G is a schematic view of another further embodiment of the fastening base 100. In this embodiment, the protruded blocks 110 are manufactured separately, and are threaded with the annular substrate of the fastening base 100 via the screw bolts 120. In this embodiment, the first through holes 115 are opened on the protruded blocks 110 in advance, and the second through holes 103 are opened on the annular substrate of the fastening base 100 in advance. Before the screw bolts 120 pass through the first through holes 115 and the second through holes 103 to thread with the annular substrate, the adhesives can be applied to enhance the structural strength between the protruded blocks 110 and the annular substrate of the fastening base 100. Besides, in this embodiment, the second grooves 102 are also formed on the annular substrate of the fastening base 100 in advance so as to receive the protruded blocks 110 therein. The second grooves 102 are provided to secure and position the protruded blocks 110 transversely, and the adhesives are provided to fasten the protruded blocks 110 with the annular substrate of the fastening base 100 longitudinally. Here, the structure of the protruded blocks 110 is the same as mentioned above so as to be omitted.

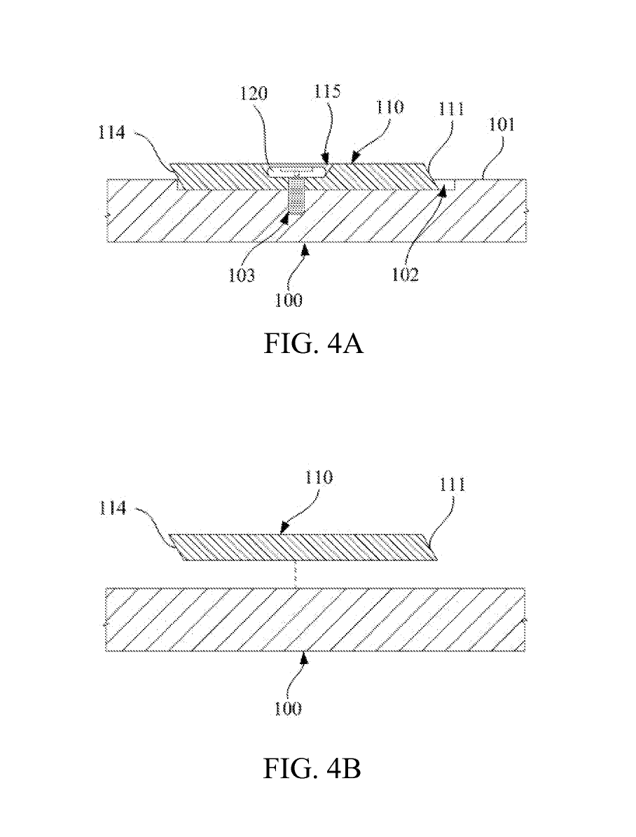

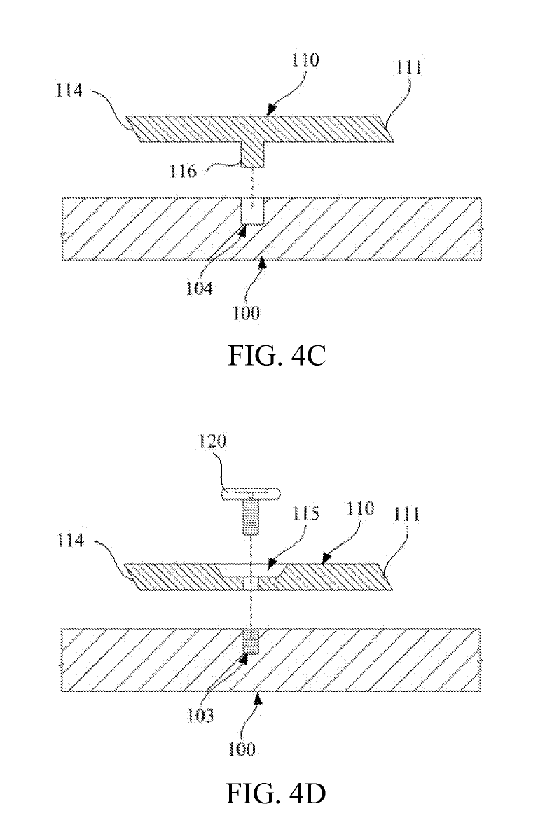

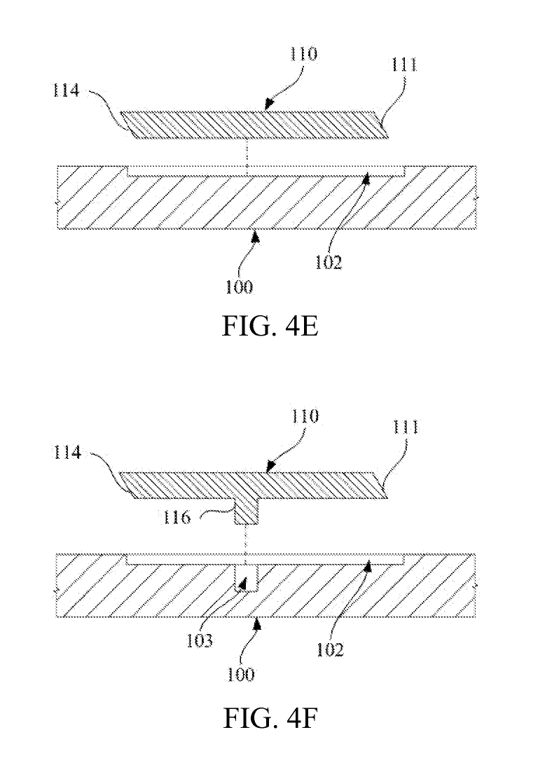

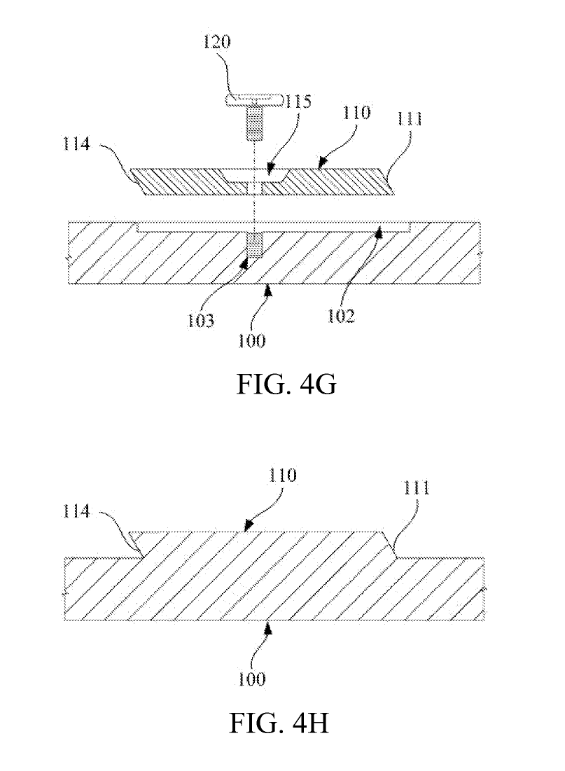

And then, please refer to FIGS. 4A to 4H, in which FIGS. 4A to 4G are the cross-sectional views of FIGS. 3A to 3G respectively, and FIG. 4H is a cross-sectional view for showing the protruded blocks 110 and the annular substrate of the fastening base 100 are formed integrally as a whole.

As shown in FIG. 4A, the screw bolt 120 is threaded with the annular substrate of the fastening base 100 via the first through hole 115 and the second through hole 103, and the second groove 102 can receive the protruded block 110 so as to position the protruded block 110.

As shown in FIG. 4B, the protruded block 110 is attached on the annular substrate of the fastening base 100 via the adhesives.

As shown in FIG. 4C, the protruded block 110 is positioned in the recessed hole 104 via the protruded rod 116, and can be attached on the annular substrate of the fastening base 100 via the adhesives.

As shown in FIG. 4D, the screw bolt 120 is threaded with the annular substrate of the fastening base 100 via the first through hole 115 and the second through hole 103.

As shown in FIG. 4E, the protruded block 110 is attached on the annular substrate of the fastening base 100 via the adhesives. And, the second groove 102 can receive the protruded block 110 so as to position the protruded block 110.

As shown in FIG. 4F, the protruded block 110 is positioned in the recessed hole 104 via the protruded rod 116, and can be attached on the annular substrate of the fastening base 100 via the adhesives. And, the second groove 102 can receive the protruded block 110 so as to position the protruded block 110.

As shown in FIG. 4G, the screw bolt 120 is threaded with the annular substrate of the fastening base 100 via the first through hole 115 and the second through hole 102, and the second groove 102 can receive the protruded block 110 so as to position the protruded block 110.

As shown in FIG. 4H, the protruded blocks 110 and the annular substrate of the fastening base 100 are formed integrally as a whole.

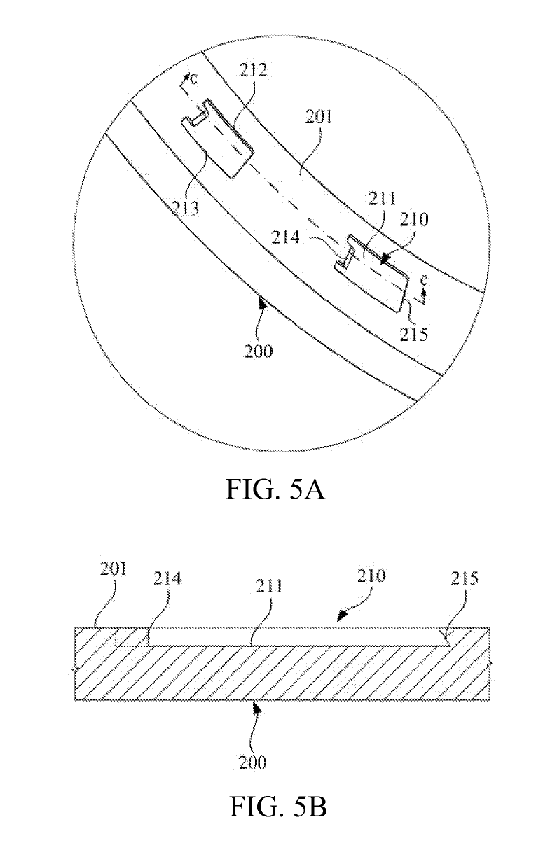

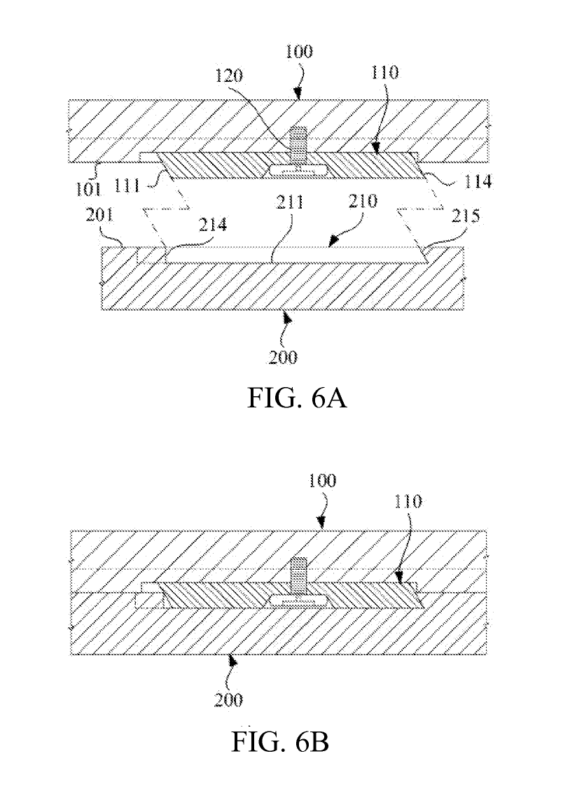

And then, please refer to FIGS. 5A to 5B, which are a partial enlarged view and a cross-sectional view of a fastening ring 200 of the disclosure respectively. The fastening ring 200 has the second combining face 201 and the first grooves 210. The first grooves 210 are annularly aligned on the second combining face 201 and provided receiving spaces for receiving the protruded blocks 110. And, parts of the flange of each first groove 210 are constituted of a second buckling face 215 (a dove-tail structure) for receiving the first buckling face 114 of the protruded block 110. The second buckling face 215 is tilted from the root portion (namely, the intersection portion of the second buckling face 215 and the second combining face 201) thereof toward the second combining face 201 along a plane radially extending along the fastening ring 200 (but embodiments of the disclosure are not limited thereto) and formed as another reversed clamp structure. The first buckling face 114 of the protruded block 110 is formed as one reversed clamp structure, and the second buckling face 215 is formed as another reversed clamp structure and parallel with the first buckling face 114. Therefore, when the adhesives are applied to attach the fastening base 100 with the fastening ring 200, the fastening ring 200 is fastened with the fastening base 100 longitudinally, as shown in FIG. 6A.

In FIG. 5A, the first groove 210 is consisting of a second top face 211, a second inner lateral face 212, a second outer lateral face 213, a second guiding face 214 and the second combining face 215. The second top face 211 is the bottom portion of a plane constituted of the first groove 210. The second inner lateral face 212 and the second outer lateral face 213 are arc faces recessed from the circumference of the fastening ring 200, and the curvature radii of the second inner lateral face 212 is smaller than the curvature radii of the second outer lateral face 213. In this embodiment, preferably, the second buckling face 215 is corresponding to the first buckling face 114 and a tilt angle thereof is 30 degrees; but embodiments of the disclosure are not limited thereto, in some embodiments, the tilt angle of the first buckling face 114 and the tilt angle of the second buckling face 215 can be defined from 1 degree to 60 degrees, and the tilt angle of the first buckling face 114 is the same as the tilt angle of the second buckling face 215, so that the first buckling face 114 is parallel with the second buckling face 215. Preferably, the second guiding face 214 is the plane radially extending along the fastening ring 200 (but embodiments of the disclosure are not limited thereto); in this embodiment, preferably, the second guiding face 214 is tilted from the root portion (the intersection portion of the second guiding face 214 and the second combining face 201) of the second guiding face 214 toward the inner side of the first groove 210. In one embodiment, the second guiding face 214 is disposed opposite to the second buckling face 215 and is parallel to the second buckling face 215.

Please refer to FIGS. 6A to 6B, upon assembling the fastening base 100 with the fastening ring 200, the axle center of the fastening base 100 is aligned with the axle center of the fastening ring 200, so that the first combining face 101 is aligned with the second combining face 201, the protruded blocks 110 are aligned with the first grooves 210, each first buckling face 114 is aligned with each corresponding second buckling face 215, the intersection portion of each second guiding face 214 and each corresponding top face 211 is aligned with each corresponding first guiding face 111, and the first inner lateral face 112 and the first outer lateral face 113 are aligned with the second inner lateral face 212 and the second outer lateral face 213 respectively. Based on this, the protruded blocks 110 are positioned with the first grooves 210 respectively. That is to say, the protruded blocks 210 are disposed in the first grooves 210. And then, the fastening base 100 and the fastening ring 200 can be rotated counterclockwise respectively along the circumference thereof, so that the protruded blocks 110 and the first grooves 210 are slid along the first buckling face 114 (or the second buckling face 215) to buckle with each other, so that the fastening ring 200 does not depart from the fastening base 100. The adhesives can be applied to the connection of the fastening base 100 and the fastening ring 200 so as to enhance the fastening force between the fastening base 100 and the fastening ring 200.

Furthermore, in the embodiments mentioned above, the first buckling face 114 is tilted leftward from a lateral view of the disclosure, so that when the fastening ring 200 is disposed on the fastening base 100, the fastening ring 200 is rotated counterclockwise so as to let the first grooves 210 receive the protruded blocks 110. In other embodiments, the first bucking face 114 is tilted rightward from a lateral view of the disclosure, so that when the fastening ring 200 is disposed on the fastening base 100, the fastening ring 200 is rotated clockwise so as to let the first grooves 210 receive the protruded blocks 110.

In addition, the structure of the protruded block 110 of the fastening base 100 and the structure of the first groove 210 of the fastening ring 200 can be exchanged. That is to say, the protruded blocks 110 can be manufactured on the fastening ring 200, and the first grooves 210 can be manufactured on the fastening base 100. Here, the structure of the protruded blocks 110 of the fastening ring 200 and the structure of the first grooves 210 of the fastening base 100 are the same as mentioned above so as to be omitted.

As compared to a conventional fastening fixture in which the fastening ring 20 is attached on the fastening base 10 via the flat attaching face 11, the fastening ring 200 and the fastening base 100 of the chemical mechanical polishing fastening fixture in accordance with the disclosure can be efficiently fastened with each other and easily manufactured, so that the lifetime of the chemical mechanical polishing fastening fixture is elongated.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A chemical mechanical polishing fastening fixture, comprising:
a fastening base, comprising:
an annular substrate, having a first combining face; and
a plurality of protruded blocks, annularly aligned on the first combing face, each protruded block being made of polyphenylene sulfide and comprising a first buckling face, the first buckling face being tilted from a root portion thereof toward an outer side of the protruded block along a plane radially extending from the annular substrate; and
a fastening ring, having a second combing face and a plurality of first grooves, the first grooves being annularly aligned on the second combining face, parts of a flange of each first groove being constituted of a second buckling face, the second buckling face being tilted from a root portion thereof toward the second combining face;
wherein when the protruded blocks are disposed in the first grooves, the fastening base and the fastening ring are rotated counterclockwise respectively along the circumference thereof, so that the first buckling face of the protruded block is buckled with the second buckling face of the first groove.

2. The chemical mechanical polishing fastening fixture according to claim 1, wherein each protruded block has a first through hole, and the first combining face of the annular substrate has a plurality of second through holes, each second through hole is corresponding to and is opposite to each corresponding first through hole, a screw bolt is passing through and threaded with the first through hole and the second through hole, so that the protruded block is fastened on the annular substrate.

3. The chemical mechanical polishing fastening fixture according to claim 2, wherein the annular substrate further comprises a plurality of second grooves, each second groove receives each corresponding protruded block so as to prevent each corresponding protruded block from sliding.

4. The chemical mechanical polishing fastening fixture according to claim 1, wherein each protruded block has a protruded rod, and the first combining face of the annular substrate has a plurality of recessed holes, the protruded rods are inserted into the recessed holes, so that the protruded blocks are fastened on the annular substrate.

5. The chemical mechanical polishing fastening fixture according to claim 4, wherein the annular substrate further comprises a plurality of second grooves, each second groove receives each corresponding protruded block so as to prevent each corresponding protruded block from sliding.

6. The chemical mechanical polishing fastening fixture according to claim 1, wherein a first tilt angle defined between the first buckling face and the second buckling face is defined from 1 degree to 60 degrees, and the first buckling face is parallel to the second buckling face.

7. The chemical mechanical polishing fastening fixture according to claim 1, wherein the protruded block further comprises a first guiding face, disposed opposite to the first buckling face and parallel to the first buckling face.

8. The chemical mechanical polishing fastening fixture according to claim 7, wherein the first groove further comprises a second guiding face, disposed opposite to the second buckling face and is parallel to the second buckling face.

9. The chemical mechanical polishing fastening fixture according to claim 8, wherein a second tilt angle defined between the first guiding face and the second guiding face is defined from 1 degree to 60 degrees, and the first guiding face is parallel to the second guiding face.

10. A fastening base of a chemical mechanical polishing fastening fixture, provided to combine with a fastening ring so as to form the chemical mechanical polishing fastening fixture, in which the fastening ring has a second combining face and a plurality of first grooves, in which the first grooves are annularly aligned on the second combining face, in which parts of a flange of each first groove are constituted of a second buckling face, in which the second buckling face is tilted from a root portion thereof toward the second combining face, the fastening base comprising:
an annular substrate, having a first combining face; and
a plurality of protruded blocks, annularly aligned on the first combining face, each protruded block being made of polyphenylene sulfide and comprising a first buckling face, the first buckling face being tilted from a root portion thereof toward an outer side of the protruded block along a plane radially extending from the annular substrate;
wherein when the protruded blocks are disposed in the first grooves, the fastening base and the fastening ring are rotated counterclockwise respectively along the circumference thereof, so that the first buckling face of the protruded block is buckled with the second buckling face of the first groove.

11. The fastening base of the chemical mechanical polishing fastening fixture according to claim 10, wherein each protruded block has a first through hole, and the first combining face of the annular substrate has a plurality of second through holes, each second through hole is corresponding to and is opposite to each corresponding first through hole, a screw bolt is passing through and threaded with the first through hole and the second through hole, so that the protruded block is fastened on the annular substrate.

12. The fastening base of the chemical mechanical polishing fastening fixture according to claim 10, wherein the annular substrate further comprises a plurality of second grooves, each second groove receives each corresponding protruded block so as to prevent each corresponding protruded block from sliding.

13. The fastening base of the chemical mechanical polishing fastening fixture according to claim 10, wherein each protruded block has a protruded rod, and the first combining face of the annular substrate has a plurality of recessed holes, the protruded rods are inserted into the recessed holes, so that the protruded blocks are fastened on the annular substrate.

14. The fastening base of the chemical mechanical polishing fastening fixture according to claim 13, further comprising a plurality of second grooves, each second groove receiving each corresponding protruded block so as to prevent each corresponding protruded block from sliding.

15. The fastening base of the chemical mechanical polishing fastening fixture according to claim 10, wherein a first tilt angle defined between the first buckling face and the second buckling face is defined from 1 degree to 60 degrees, and the first buckling face is parallel to the second buckling face.

16. The fastening base of the chemical mechanical polishing fastening fixture according to claim 10, wherein the protruded block further comprises a first guiding face, disposed opposite to the first buckling face and parallel to the first buckling face.

17. The fastening base of the chemical mechanical polishing fastening fixture according to claim 16, wherein the first groove further comprises a second guiding face, disposed opposite to the second buckling face and is parallel to the second buckling face.

18. The fastening base of the chemical mechanical polishing fastening fixture according to claim 17, wherein a second tilt angle defined between the first guiding face and the second guiding face is defined from 1 degree to 60 degrees, and the first guiding face is parallel to the second guiding face.

19. A chemical mechanical polishing fastening fixture, comprising:
a fastening ring, comprising:
an annular substrate, having a first combining face; and
a plurality of protruded blocks, annularly aligned on the first combing face, each protruded block being made of polyphenylene sulfide and comprising a first buckling face, the first buckling face being tilted from a root portion thereof toward an outer side of the protruded block along a plane radially extending from the annular substrate; and
a fastening base, having a second combing face and a plurality of first grooves, the first grooves being annularly aligned on the second combining face, parts of a flange of each first groove being constituted of a second buckling face, the second buckling face being tilted from a root portion thereof toward the second combining face;
wherein when the protruded blocks are disposed in the first grooves, the fastening base and the fastening ring are rotated counterclockwise respectively along the circumference thereof, so that the first buckling face of the protruded block is buckled with the second buckling face of the first groove.

20. The chemical mechanical polishing fastening fixture according to claim 19, wherein a first tilt angle defined between the first buckling face and the second buckling face is defined from 1 degree to 60 degrees, and the first buckling face is parallel to the second buckling face.

21. The chemical mechanical polishing fastening fixture according to claim 19, wherein the protruded block further comprises a first guiding face, disposed opposite to the first buckling face and parallel to the first buckling face.

22. The chemical mechanical polishing fastening fixture according to claim 21, wherein the first groove further comprises a second guiding face, disposed opposite to the second buckling face and is parallel to the second buckling face.

23. The chemical mechanical polishing fastening fixture according to claim 22, wherein a second tilt angle defined between the first guiding face and the second guiding face is defined from 1 degree to 60 degrees, and the first guiding face is parallel to the second guiding face.
